(19) United States
(12) Patent Application Publication
(10) Pub. No.: US 2010/0289138 A1
(43) Pub. Date: Nov. 18, 2010

(54) SUBSTRATE STRUCTURE FOR FLIP-CHIP INTERCONNECT DEVICE

(76) Inventor: Kenji Masumoto, Hayami-gun (JP)

Correspondence Address: TEXAS INSTRUMENTS INCORPORATED, P O BOX 655474, M/S 3999, DALLAS, TX, 75265, US

(21) Appl. No.: 12/465,049

(22) Filed: May 13, 2009

(51) Int. Cl. H01L 23/485; H01L 21/56

(52) U.S. Cl. 257/737; 438/108; 257/778; 257/E23.021; 257/E21.503

(57) ABSTRACT

An integrated circuit (IC) and a method of forming the device are provided. The device includes a substrate and a metal trace formed on the substrate, the metal trace including a bond area and a routing area. The routing area includes a rough surface for promoting adhesion to underfill of a flip-chip die. The flip-chip die can include a bump bond connected to the bond area of the metal trace. The underfill is between the substrate and an active surface of the flip-chip die, the rough surface of the routing area adhering to the underfill in the absence of a photo resist on the routing area of the metal trace.

### FIELD

This invention relates generally to a substrate structure for a flip-chip interconnect device, and more particularly configuring an increased available clearance and promoting underfill adhesion to the substrate structure.

### BACKGROUND

Bumped die of flip chip assemblies are attached to a substrate and the space between the die and substrate is filled with an electrically non-conductive underfill material. The conductive bump provides an electrically conductive path from the chip to the substrate The conductive bump also provides a thermally conductive path to carry heat from the chip to the substrate. Additionally, the conductive bump acts as a spacer, preventing electrical contact between the chip and substrate.

In a typical process, gold is used to form the conductive bumps on the chip. The chip is then flipped so that the conductive bumps face downward and are aligned with other bond pads on a substrate. Once aligned, each conductive bump is electrically and mechanically connected to a corresponding substrate bond pad using solder. Gold bump flip chips may be attached to the substrate bond pads with an electrically conductive adhesive or by thermosonic gold-to-gold connection. The surface of the chip may be covered with a protective polymer overcoat such as polyimide (PIQ) or poly-benzoxasole (PBO). The surface of the substrate may be covered with a solder resist. The surface of the substrate may be further covered with a photo resist.

Typically, the protective overcoat is approximately 5 μm thick, and solder resist is approximately 30 μm thick. The stand-off height for typical stud bumps is approximately 36 μm, and bond pads are typically 15 μm thick. The resulting gap between bond pads on the chip and bond pads on the substrate is approximately 35 μm, and the gap between the protective overcoat on the chip and solder resist on the substrate is approximately 15 μm. The underfill adhesive must flow in these gaps to fill all the space between the chip and the substrate. An increased gap clearance can maximize an amount of underfill and corresponding adhesion between components.

Several known solutions to increase a gap clearance between a substrate and chip, as well as increase adhesion properties between the underfill and substrate currently exist. One solution includes forming two or more conductive bumps on top of each other, thereby increasing the space in which the underfill flows. Another known method of increasing clearance between the chip and substrate is to remove a polybenzoxazole PBO layer from the chip. Yet another proposed method of increasing clearance between the chip and substrate is to remove solder resist from a Ni/Au plated copper trace. It has been further proposed to eliminate the Ni/Au plating of the copper trace. Finally, it has been proposed to directly cover the copper trace with the solder resist material. The organic solder resist is provided to promote adhesion between a die underfill material and the metal traces of a substrate.

In an Au—Au bonding scheme, the bump stand off can be as low as 15-20 nm, and the solder resist must, therefore, be very thin. For example, the solder resist can be less than 10 μm thick. With such thin depositions of solder resist, it becomes problematic to maintain uniform coverage of the solder resist.

### BRIEF SUMMARY

Accordingly, it is a purpose of the exemplary embodiments herein to promote adhesion of underfill to the substrate by incorporating a surface treatment of the metal trace formed on the substrate, and at the same time increasing an underfill clearance between the substrate and the chip. The metal trace can be physically defined to include a bond area and a routing area. The surface treatment includes a roughening of only the routing area of the metal trace, and specifically the exposed surface of the routing area absent a solder resist layer thereon. The rough surface, absent a solder resist layer, not only promotes adhesion between the routing area of the metal trace and the underfill, but increases a gap within which the underfill can be accommodated. The increased gap size is due to the absence of the solder resist.

The exemplary embodiments have an advantage of reduced manufacturing time, particularly over the use of stacked bumps, which have the further disadvantage of being weaker than single bumps. A further advantage is found over the solution to remove the protection die surface because reliability tests show moisture absorption and reflow heating causing delamination at the interface of the underfill and Ni/Au plating. Yet another advantage exist over the solution to simply remove the solder resist, in that a flat copper surface exhibits poor adhesion to the underfill material.

These and other problems are generally solved or circumvented, and technical advantages are generally achieved, by preferred embodiments of the present invention in which a substrate structure, particularly a copper trace surface thereof, is prepared to promote adhesion to an underfill material, even in the absence of plating and solder resist, thereby creating a maximum gap for underfill in an Au-Au flip chip bonding configuration.

Additional embodiments of the disclosure will be set forth in part in the description which follows, and in part will be obvious from the description, or may be learned by practice of the present disclosure. The embodiments of the disclosure will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE DRAWINGS

The invention is best understood from the following detailed description when read with the accompanying FIGURES. It is emphasized that in accordance with the standard practice in the semiconductor industry, various features may not be drawn to scale. In fact, the dimensions of various features may be arbitrarily increased or reduced for clarity of discussion. Reference is now made to the following descriptions taken in conjunction with the accompanying drawings, in which:

FIG. 1 is a side view depicting an exemplary flip-chip integrated circuit (IC) device;

FIG. 2 is a top view of an exemplary metal trace of the IC device of FIG. 1;

FIG. 3A is a diagram illustrating a step of forming an exemplary flip-chip IC device according to certain embodiments;

FIG. 3B is a diagram illustrating another step of forming an exemplary flip-chip IC device according to certain embodiments;

FIG. 3C is a diagram illustrating yet another step of forming an exemplary flip-chip IC device according to certain embodiments;

FIG. 3D is a diagram illustrating yet another step of forming an exemplary flip-chip IC device according to certain embodiments;

FIG. 3E is a diagram illustrating yet another step of forming an exemplary flip-chip IC device according to certain embodiments; and

FIG. 4 is a flow diagram depicting an exemplary method of forming a flip-chip IC device according to certain embodiments.

### DETAILED DESCRIPTION

Reference will now be made in detail to the exemplary embodiments of the present disclosure, an example of which is illustrated in the accompanying drawings. Wherever possible, the same reference numbers will be used throughout the drawings to refer to the same or like parts.

In the following description, reference is made to the accompanying drawings that form a part thereof, and in which is shown by way of illustration specific exemplary embodiments which may be practiced. These embodiments are described in sufficient detail to enable those skilled in the art to practice the embodiments and it is to be understood that other embodiments may be utilized and that changes may be made without departing from the scope of the invention. The following description is, therefore, merely exemplary.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10″” can include any and all sub-ranges between (and including) the minimum value of zero and the maximum value of 10, that is, any and all sub-ranges having a minimum value of equal to or greater than zero and a maximum value of equal to or less than 10, e.g., 1 to 5.

According to embodiments, FIG. 1 is a side view depicting an integrated circuit device 100 incorporating an exemplary substrate structure 110. It should be readily apparent to those skilled in the art that FIG. 1 is exemplary and that other elements can be added, removed or modified without departing from the scope of the exemplary embodiments.

As depicted, the exemplary substrate structure 110 can be incorporated into a flip-chip IC semiconductor device 100. While FIG. 1 depicts several components of the flip-chip device 100, one skilled in the art will realize that device 100 can include any number and type of components. The flip-chip device 100 can include a substrate 120, metal traces 130 formed on the substrate 120, a surface layer (e.g. plating) material 140 formed on the metal traces 130, a die 150 connected to the substrate 120 via a bump bond 160, and underfill 170.

The substrate 120 of the flip-chip device can be formed of a material, using any process, to any dimension and specification, as known in the art. For example, substrate 120 can be a single or multi-layer substrate. In addition, the die 150 can be formed of a material and components, using any process, to any dimension and specification, as known in the art. The die 150 can further include bump bond 160 formed thereon as known in the art of flip-chip technology. While various bump bonds are known, exemplary embodiments herein are directed to gold stud bumps, for interconnection of the die 150 to the substrate 120. Although only one bump bond 160 is depicted for simplicity of description, it will be appreciated that multiple bump bonds 160 and patterns of bump bonds 160 can be utilized in the interconnection as known in the art.

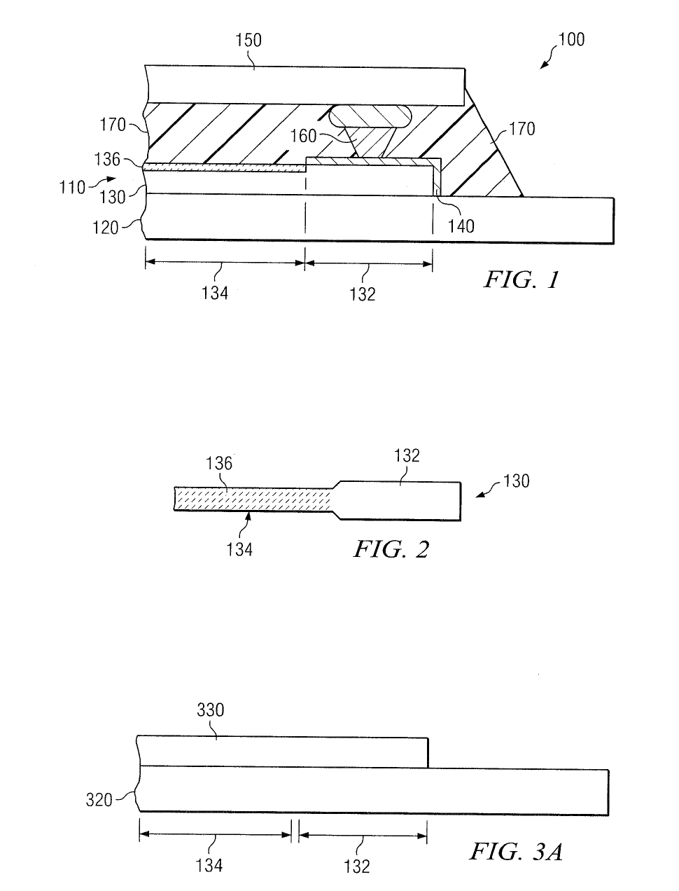

The metal trace 130 can be formed on a surface of the substrate 120 using any process, to any dimension and specification, as known in the art. In the exemplary embodiments, the metal trace 130 can be a copper trace. The copper trace 130 can include a bond finger area 132 and a routing area 134. A top plan view of a single copper trace 130 is depicted in FIG. 2 for further clarity. In each of FIGS. 1 and 2, the approximate regions of the bond finger area 132 and the routing area 134 are depicted. In FIG. 1, the dimension depiction is found in substrate 120 for ease of viewing, however, it will be appreciated that the dimension is referring to that of the copper trace 130. The delineation of the bond finger area 132 from the routing area 134 can vary according to a final shape, deposition process, etc., of the copper trace 130.

The surface layer material 140 can be a plating material. The surface layer 140 can be formed on an exposed surface of the bond finger area 132 of the copper trace 130, The surface layer 140 can be formed using any process, to any dimension and specification, as known in the art. For example, the bond finger area 132 can include a Ni/Au surface layer 140. The surface layer 140 can be such that the Ni is deposited, followed by Au deposition. The surface layer 140 can be a Ni/Au plating layer with the Au exposed for contact with the Au bump bond 160. The Au—Au bonding is exemplary to certain embodiments herein because of the reduced clearance between the substrate 120 and active surface of the die 150 in such an interconnection.

The underfill 170 can include any type of known material which can surround and encapsulate components prior to hardening, such as a form of hard-curing plastic or epoxy resin.

In the known art, a solder resist is deposited in the bond finger area 134. Solder resist is a polymer coating, which provides a permanent protective layer on surface features, such as copper traces, of a printed circuit board except the specific areas where it is required to form solder joints. The solder resist can provide electrical insulation and protection against oxidation and corrosion. However, the solder resist, on a surface of the metal trace 130, can substantially reduce a clearance between the substrate 120 and an active surface of the die 150. In an Au-Au flip-chip bonding scheme, the clearance reduction can substantially impair an amount of underfill 170 supplied for bonding components within the package. In addition, the reduced clearance becomes problematic in the actual supply of underfill 170 to the area.

In order to improve clearance between the substrate 120 and the die 150, exemplary embodiments herein remove the solder resist. In other words, the substrate 120 is free of a solder resist. However, the underfill 170 can have poor adhesion to the substrate 120, and in particular to a surface of the routing area 134 of the metal trace 130 formed on the substrate 120, absent the solder resist in a flip-chip package 100. Accordingly, in order to promote adhesion to the surface of the routing area 134, the surface of the routing area 134 can include a rough surface 136. The rough surface 136 can be obtained from a surface roughness treatment. The surface roughness treatment can be specific to the routing area 134, and can impart surface roughness to a depth of about 0.5 μm to about 3.0 μm of the routing area 134. For example, in a copper routing area 134, the routing area 134 can be treated with a chemical to achieve the desired surface roughness. The chemical can include a CZ treatment, supplied by Mec Co. Ltd.™.

The surface roughness treatment to impart the rough surface 136 can be prior to plating of the bond finger area 132. Likewise, the surface roughness treatment to impart the rough surface 136 can be subsequent to plating of the bond finger area 132. In each instance, suitable masks (not shown) can be applied and removed as known in the art for protecting either the bond finger area 132 or the routing area 134.

Because of the surface roughness treatment, the copper routing area 134 will adhere to the underfill 170 even absent the solder resist. In addition, the widest available gap is available for an underfilling process. It will be appreciated that the surface roughness treatment can be such that an upper planar surface of the rough surface 136 can be substantially co-planar with the plating layer 140 of the bond finger area 132.

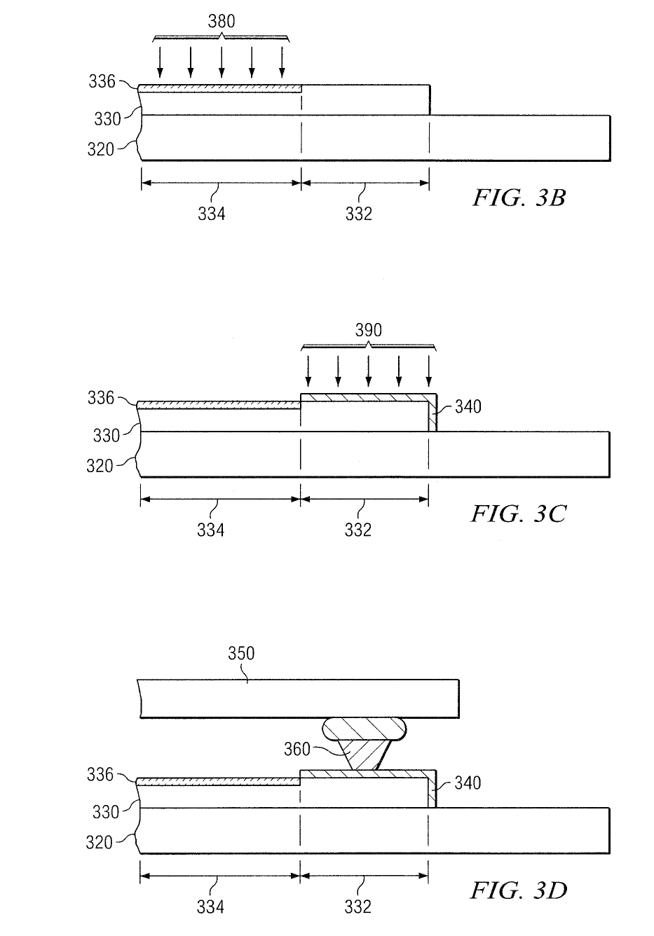

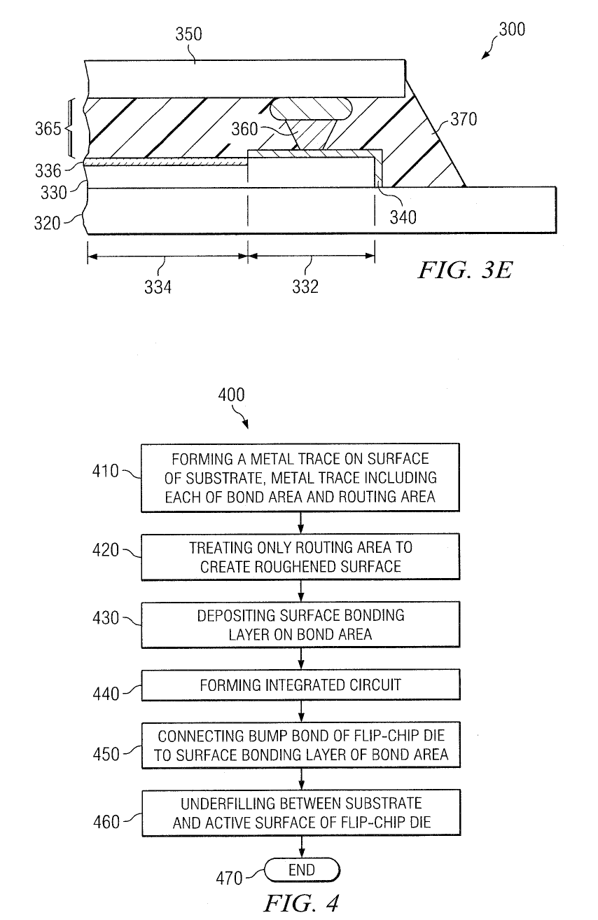

FIGS. 3A through 3E illustrate formation of an exemplary flip-chip device 300 (FIG. 3E) having a substrate 320 according to certain embodiments. It should be readily apparent to those skilled in the art that FIGS. 3A through 3E are exemplary and that other elements and steps can be added, removed or modified without departing from the scope of the exemplary embodiments.

FIG. 3A depicts an exemplary substrate 320 and a metal trace 330 formed on the substrate 320. In certain embodiments, the metal trace 330 can include a bond finger area 332 and a routing area 334. The metal trace 330 can be a copper metal trace. Each of the substrate 320 and the copper trace 330 can be formed of a material, using any process, to any dimension and specification, as known in the art, and details of these components need not be described further herein.

FIG. 3B depicts an exemplary surface treatment 380 of the metal trace 330, particularly at the routing area 334 thereof. The surface treatment 380 results in a rough surface 336 of the metal trace routing area 334. It will be appreciated that the bond finger area 332 can be masked or otherwise protected during the surface treatment 380 of the routing area 334.

In certain embodiments, the surface treatment 380 can impart surface roughness to a depth of about 0.5 μm to about 3.0 μm of the routing area 334. For example, in a copper routing area 334, the routing area 334 can be treated with a chemical to achieve the desired surface roughness 336. The chemical can include a CZ treatment, supplied by Mec Co. Ltd.™.

FIG. 3C depicts an exemplary plating 390 of the metal trace 330, particularly at the bond finger area 332 thereof. It will be appreciated that the routing area 334 can be masked or otherwise protected during plating 390 of the bond finger area 332.

In certain embodiments, the plating 390 can include a Ni/Au surface layer 340. The surface layer 340 can be such that the Ni is deposited, followed by Au deposition. The surface layer 340 can be a Ni/Au plating layer with the Au exposed for contact with an Au bump bond, subsequently in FIG. 3D.

While FIG. 3B is depicted as occurring prior to FIG. 3C, it will be appreciated that the surface roughness treatment 380 and the bond finger plating 390 can occur in either order, and the order can be determined according to flip-chip processing parameters.

FIG. 3D depicts an exemplary bonding of a bump bond 360 of a die 350 to the plating layer 340 of the substrate metal trace 330 of substrate 320.

In certain embodiments, the bump bond 360 can be an Au bump bond, for example an Au stud bump. The bump bond 360 can be formed on an active surface of the die 350; The bump bond 360 can provide an electrical interconnection of the die 350 to the substrate 320 as known in the art. Although only one bump bond 360 is depicted for simplicity of description, it will be appreciated that multiple bump bonds 360 and patterns of bump bonds 360 can be utilized in the interconnection.

FIG. 3E depicts an exemplary supply of underfill 370 within a clearance 365 as defined by the bump bond 360 between the substrate 320 and an active surface of the die 350.

In certain embodiments, the underfill 370 can include any type of known material which can surround and encapsulate components prior to hardening, such as a form of hard-curing plastic or epoxy resin.

Because of the surface roughness treatment 380, the rough surface 336 of copper routing area 334 will adhere to the underfill 370 even absent the solder resist. In addition, the widest available gap 365 is available for an underfilling process.

It will be appreciated that while the rough surface 336 of the copper trace routing area 334 is disclosed and described in connection with a flip-chip device 300, that exemplary embodiments are well suited to other semiconductor device support surfaces which can require additional clearance and promote adhesion between components. Accordingly, depiction and description of a surface roughness treatment 380 to obtain a rough surface 336 of the copper trace routing area 334 is not intended to limit the scope of exemplary embodiments.

FIG. 4 is a flow diagram illustrating a method 400 of forming a substrate structure in a semiconductor device, consistent with embodiments of the present disclosure. In exemplary embodiments, the semiconductor device can be a flip-chip IC device. It should be readily apparent to those skilled in the art that FIG. 4 is exemplary and that other steps can be added or existing steps can be removed or modified without departing from the scope of the exemplary embodiments.

Method 400 begins at 410 with forming a metal trace on a surface of the substrate, the metal trace comprising a bond area and a routing area. The metal trace comprises copper. At least the routing area is free of a solder resist.

In 420, the method can include treating only the routing area to comprise a roughened surface, the roughened surface promoting adhesion with an underfill material. The roughened surface can include surface roughness to a depth of about 0.5 μm to about 3.0 μm.

In 430, the method can include depositing one of an Au or a Ni/Au surface layer on the bond area. It will be appreciated that the treating of only the routing area can be prior to deposition of Au or Ni/Au. Likewise, treating of only the routing area can be subsequent to deposition of Au or Ni/Au.

The method can include further implementing the method in a method of forming an integrated circuit. Forming an integrated circuit can include, at 440, connecting a bump bond of the flip-chip die to the bond area at 450. The bump bond can be an Au bump bond. Forming an integrated circuit can also include, at 460, underfilling between the substrate and an active surface of the flip-chip die, the rough surface of the routing area promoting adhesion of the routing area with the underfill.

In 470, the method can end, but the method can return to any point and repeat.

Thus, the exemplary embodiments promote adhesion between a roughened surface of a copper trace and underfill material, the roughened surface in the routing area of the copper trace which is further free of a solder resist thereon. Numerous technical advantages are provided by the exemplary embodiments, including but not limited to improved package strength, resilience, longevity, manufacturability, and reliability.

While the invention has been described with reference to the exemplary embodiments thereof, those skilled in the art will be able to make various modifications to the described embodiments without departing from the true spirit and scope. The terms and descriptions used herein are set forth by way of illustration and are not meant as limitations. In particular, although the method has been described by examples, the steps of the method may be performed in a different order than illustrated or simultaneously. Furthermore, to the extent that the terms “including”, “includes”, “having”, “has”, “with”, or variants thereof are used in either the detailed description and the claims, such terms are intended to be inclusive in a manner similar to the term “comprising”. As used herein, the term “one or more of” with respect to a listing of items such as, for example, A and B, means A alone, B alone, or A and B.

Other embodiments of the present disclosure will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A substrate structure for an underfilled flip-chip integrated circuit (IC) device, the substrate comprising:
a metal trace formed on a surface of the substrate, the metal trace comprising a bond area and a routing area, each of the bond area and routing area comprising an outer contact surface;
only the routing area comprising a rough surface, the rough surface having a reduced height relative to the bond area.

2. The substrate of claim 1, wherein the rough surface comprises surface roughness to a depth of about 0.5 μm to about 3.0 μm.

3. The substrate of claim 1, wherein at least the routing area is free of a solder resist.

4. The substrate of claim 1, wherein the bond area comprises an upper layered surface of solder resist and photo resist.

5. The substrate of claim 1, wherein the bond area comprises a surface suitable for forming a solder free joint.

6. The substrate of claim 1, wherein a bump bond of a flip-chip comprises an Au bump bond.

7. An integrated circuit (IC) device comprising:
a substrate;
a metal trace formed on the substrate, the metal trace comprising a bond area and a routing area, each of the bond area and routing area comprising an outer contact surface;
only the routing area comprising a rough surface, the rough surface having a reduced height relative to the bond area;
a flip-chip die comprising a bump bond, the bump bond connected to the bond area; and
an underfill between the substrate and an active surface of the flip-chip die, the rough surface of the routing area promoting adhesion of the routing area with the underfill.

8. The device of claim 7, wherein surface roughness comprises roughness to a depth of about 0.5 μm to about 3.0 μm.

9. The device of claim 7, wherein at least the routing area is free of a solder resist.

10. The device of claim 7, wherein the bond area comprises an upper layered surface of solder resist and photo resist.

11. The device of claim 7, wherein the bond area comprises a surface suitable for forming a solder free joint.

12. The device of claim 7, wherein the bump bond comprises an Au bump bond.

13. A method of forming an underfilled flip-chip integrated circuit (IC) device, the method comprising:
forming a metal trace on a surface of a substrate, the metal trace comprising a bond area and a routing area, each of the bond area and routing area comprising an outer surface; and
treating only the routing area to comprise a roughened surface, the roughened surface having a reduced height relative to the bond area and promoting adhesion with an underfill material,
connecting a bump bond of the flip-chip die to the bond area; and
underfilling between the substrate and facing surface of the flip-chip die.

14. The method of claim 13, wherein the roughened surface comprises surface roughness to a depth of about 0.5 μm to about 3.0 μm.

15. The method of claim 13, wherein the metal trace comprises copper.

16. The method of claim 13, wherein at least the routing area is free of a solder resist.

17. The method of claim 13, further depositing one of an Au or a Ni/Au surface layer on the bond area.

18. The method of claim 17, wherein treating is prior to Au or Ni/Au deposition.

19. The method of claim 18, wherein treating is subsequent to Au or Ni/Au deposition.

20. The method of claim 13, wherein the bump bond comprises an Au bump bond.
